(19) United States
(12) Patent Application Publication
(10) Pub. No.: US 2026/0177213 A1
(43) Pub. Date: Jun. 25, 2026

(54) A PHOTOREACTOR ASSEMBLY

(71) Applicant: SIGNIFY HOLDING B.V., EINDHOVEN (NL)

(72) Inventors: TIES VAN BOMMEL, HORST (NL); RIFAT ATA MUSTAFA HIKMET, EINDHOVEN (NL)

(21) Appl. No.: 19/124,516

(22) PCT Filed: Oct. 10, 2023
(86) PCT No.: PCT/EP2023/077980

§ 371 Date: Apr. 25, 2025

(30) Foreign Application Priority Data
Oct. 25, 2022 (EP) 22203566.9

(51) Int. Cl. F21K 9/64; G03B 21/20; H01S 5/14; H01S 5/42

(52) U.S. Cl. CPC F21K 9/64; G03B 21/204; H01S 5/141; H01S 5/423

(57) ABSTRACT

A photoreactor assembly (1000) is disclosed comprising a light generating system (700) and a photoreactor (200). The light generating system comprises a first light generating device (10) configured to generate first device light (11) comprising one or more of ultraviolet light, visible light, and infrared light. The photoreactor comprises a reactor chamber (210) configured to host a fluid (5) to be treated with the first device light (11). The first light generating device (10) is controllable at least with respect to the wavelength of the first device light (11), and is configured to generate the first device light (11) such that it changes between at least two centroid wavelengths (λ1c, 1, λ1c,2) having a wavelength difference of at least 10 nm.

### TECHNICAL FIELD

The present invention relates to a photoreactor assembly comprising a light generating system, a photoreactor, and a control system.

### BACKGROUND

Photoreactors are known in the art. A photochemical reactor is a type of photoreactor which uses light to perform a chemical reaction, wherein one or more substances such as a fluid to be treated in the photochemical reactor is irradiated by light.

### SUMMARY

Chemical reactions may need a high intensity of the light irradiating the one or more substances and the light may need to have a wavelength in a particular wavelength range or at a particular wavelength value in order to facilitate or enable a large production scale and/or efficiency or yield. When light irradiating the one or more substances has an intensity or a wavelength that is undesired (e.g., not optimal), the chemical reaction may result in useless byproducts and/or there may be relatively high losses. It may therefore be desired to use a light source in a photochemical reactor which is capable of emitting light having a relatively high intensity and/or a having wavelength that is in a particular desired wavelength range or at a particular desired wavelength value.

In view of the above, a concern of the present invention is to provide a photoreactor assembly comprising a light generating system and a reactor chamber in which a fluid to be treated with light is hosted, by which photoreactor assembly it may be facilitated or allowed for generating light to be used for treatment of the fluid, which light has a relatively high intensity and/or a wavelength that is in a particular desired wavelength range or at a particular desired wavelength value.

To address at least one of this concern and other concerns, a photoreactor assembly in accordance with the independent claim is provided. Preferred embodiments are defined by the dependent claims.

According to an aspect, a photoreactor assembly is provided. The photoreactor assembly (or “reactor assembly”, or “assembly”) comprises a light generating system, a photoreactor, and a control system. The light generating system comprises a first light generating device. The first light generating device is configured to generate first device light comprising one or more of ultraviolet (UV) light, visible light, and infrared (IR) light. The first light generating device may comprise one or more of a laser (or laser-based light source) and a superluminescent diode. The photoreactor comprises a reactor chamber, which is configured to host a fluid (or “reactor fluid”, or “reactor chamber fluid”) to be treated with the first device light. The reactor chamber is configured in a light-receiving relationship with the first light generating device such that the first device light irradiates at least a part of the fluid. The first light generating device is controllable at least with respect to the wavelength of the first device light and configured to generate (e.g., in an operational mode of the light generating system) the first device light such that it changes between at least two centroid wavelengths having a wavelength difference of at least 10 nm with a selected changing frequency. To that end, the first light generating device may comprise or be constituted by a wavelength-variable light generating device (e.g., a single wavelength-variable light generating device) that is controllable at least with respect to the wavelength of the first device light and configured to generate (e.g., in an operational mode of the light generating system) the first device light such that it changes between at least two centroid wavelengths having a wavelength difference of at least 10 nm with a selected changing frequency. The control system may be configured to obtain at least one of a signal generated by user input at a user interface, a signal generated by a sensor, or a signal generated by a timer, and control the first light generating device (or, e.g., the wavelength-variable light generating device) to generate the first device light responsive to the obtaining of the at least one of the signal generated by user input at the user interface, the signal generated by the sensor, or the signal generated by the timer.

The photoreactor assembly may for example comprise or be constituted by a photochemical reactor assembly. Thus, the photoreactor may comprise or be constituted by a photochemical reactor. Photochemical processing or photochemistry relates to the chemical effect of light. More in general photochemistry refers to a (chemical) reaction caused by absorption of light. Photochemistry may for instance be used to synthesize specific products. For instance, isomerization reactions or radical reactions may be initiated by light. Other naturally occurring processes that are induced by light are, e.g., photosynthesis, or the formation of vitamin D with sunlight. Photochemistry may further, e.g., be used to degrade/oxidize pollutants in water or, e.g., air. Photochemical reactions may be carried out in a photochemical reactor. One of the benefits of photochemistry is that reactions can be performed at lower temperatures than conventional thermal chemistry and partly for that reason thermal side reactions that generate unwanted by-products are avoided.

As mentioned, the first light generating device is configured to generate first device light comprising one or more of UV light, visible light, and IR light and comprises one or more of a laser (or laser-based light source) and a superluminescent diode. Use of such light source(s) in the first light generating device may facilitate generating the first device such that it has a relatively high intensity and/or a wavelength that is in a particular desired wavelength range or at a particular desired wavelength value. This may be particularly advantageous in photochemistry applications; as mentioned, the photoreactor assembly may comprise or be constituted by a photochemical reactor assembly. In contrast, commonly used light sources in photochemistry may include low or medium pressure mercury lamps or fluorescent lamps, which may not be able to provide light in a very specific wavelength region, which may be desired or even required in photochemistry applications. Some (chemical) reactions may require a very specific wavelength region, and they may even be hampered by light from the light source emitted at other wavelengths. In these cases, part of the spectrum may have to be filtered out, which may lead to a low efficiency and complex reactor design.

In the context of the present application, the term “light” may not be limited to (only) visible light, but may encompass at least ultraviolet radiation, which accordingly may be referred to as “ultraviolet light” herein, and/or infrared radiation, which accordingly may be referred to as “infrared light” herein. Thus, in the context of the present application, the terms “light” and “radiation” can interchangeably be used, unless clear from the context that the term “light” only refers to visible light. The terms “light” and “radiation” may thus refer to UV radiation, visible light, and IR radiation.

According to one or more embodiments of the present invention, the light generating system comprises a first light generating device configured to generate first device light comprising one or more of ultraviolet light, visible light, and infrared light. Thus, in the context of the present application, by a light generating system, it is meant a system not necessarily only capable of generating visible light, but which, in alternative or in addition, may be capable of generating ultraviolet radiation and/or infrared radiation.

As mentioned, the first light generating device may comprise or be constituted by a wavelength-variable light generating device (e.g., a single wavelength-variable light generating device). Controlling of the first light generating device as described herein may refer to controlling the wavelength-variable light generating device of the first light generating device.

The term “visible light” as used herein may refer to light having one or more wavelengths in the wavelength range of (about) 380 nm-780 nm. The term “UV light” or “UV radiation” as used herein may refer to light (or radiation) having a wavelength selected from the wavelength range of 190 nm-380 nm, such as 200 nm-380 nm. The term “IR light” or “IR radiation” as used herein may refer to light (or radiation) having a wavelength selected from the wavelength range of 780 nm-3000 nm, such as 780 nm-2000 nm.

By the first light generating device being controllable at least with respect to the wavelength of the first device light and configured to generate the first device light such that it changes between at least two centroid wavelengths having a wavelength difference of at least 10 nm with a selected changing frequency, providing of the first device light such that it has a controllable spectral power distribution may be facilitated. A spectral power distribution may be characterized by a centroid wavelength. The term “centroid wavelength” may refer to the wavelength value (e.g., of the first device light) where half of the light energy is at shorter and half the energy is at longer wavelengths. It is the wavelength that divides the integral of a spectral power distribution into two equal parts as expressed by the formula λ_{c}=Σλ*I(λ)/(ΣI(λ)), where the summation is over the wavelength range of interest, and I(λ) is the spectral energy density (i.e., the integration of the product of the wavelength and the intensity over the emission band normalized to the integrated intensity). The centroid wavelength may, e.g., be determined at operation conditions. Effectively (e.g., in an operational mode of the light generating system) the first light generating device (or more precisely its first device light) may sweep between two centroid wavelengths. When changing from a first centroid wavelength to a second centroid wavelength, there may be intermediate centroid wavelengths. Therefore, the term “at least two centroid wavelengths” is used herein in relation to one or more embodiments of the present invention. The at least two centroid wavelengths may in embodiments be referred to as outer centroid wavelengths. The at least two centroid wavelengths may have a wavelength difference of at least 10 nm, such as at least 20 nm, or at least 30 nm, or at least 40 nm, or at least 60 nm, or at least 80 nm, or at least 100 nm. A difference between the at least two centroid wavelengths may be at least 40 nm, or at least 50 nm. Further, the changing frequency may be at least 40 Hz, or at least 50 Hz, or at least 60 Hz, or at least 80 Hz, or at least 100 Hz.

The change between the at least two centroid wavelengths may be a ‘jumping change’, wherein in a first time period first device light having a first centroid wavelength is provided, and wherein in a second time period first device light having a second centroid wavelength is provided, and wherein between the first time period and the second time period there is essentially no first device light having a centroid wavelength different from the at least two centroid wavelengths. However, the change between the at least two centroid wavelengths may in alternative be a sweeping change, wherein in a first time period first device light having a (the) first centroid wavelength is provided, and wherein in a second time period first device light having a (the) second centroid wavelength is provided, and wherein between the first time period and the second time period first device light having a centroid wavelength different from the at least two centroid wavelengths is provided. This may lead to first device light having a centroid wavelength changing over time between the at least two centroid wavelengths. For example, this may result in first device light having a centroid wavelength continuously changing over time between the at least two centroid wavelengths. Essentially, this may imply a continuous change during which first device light having a plurality of centroid wavelengths, respectively, may be obtained. Hence, the first light generating device may be operated continuously or pulsed. As also described elsewhere herein, the first light generating device may for example comprise a laser which may comprise or be constituted by one or more vertical cavity surface emitting laser (VCSEL) devices. The sweeping change may essentially be a continuous change from one centroid wavelength to the other, and vice versa. The sweeping change may also be a stepwise change, especially including a plurality of intermediate centroid wavelengths. When a stepwise change is used, the steps may be at maximum 5 nm, such as at maximum 2 nm.

According to one or more embodiments of the present invention, the first device light may change between the at least two centroid wavelengths in a continuous manner or in a substantially continuous manner, such as for example to momentarily attain intermediate centroid wavelength at each nm between two centroid wavelengths λ_{1c,1} and λ_{1c,2} during the change. For example, if λ_{1c,1}=380 nm and λ_{1c,2}=390 nm, the first device light may during change between these two centroid wavelengths momentarily attain the centroid wavelengths 381 nm, 382 nm, 383 nm, 384 nm, 385 nm, 386 nm, 387 nm, 388 nm, and 389 nm sequentially. This may be achieved in a ‘scanning’ manner.

The first light generating device may provide first device light having at least two different spectral power distributions at different moments in time, respectively. Hence, the first light generating device may be operated in a mode wherein during different time periods light may be produced with different spectral power distributions. In other words, as the spectral power distribution of the first light generating device may be controllable, the time dependent centroid wavelength may vary over time. The change between the at least two different spectral power distributions may be faster than an unaided (“naked”) human eye can perceive.

As mentioned, the control system may be configured to obtain at least one of a signal generated by user input at a user interface, a signal generated by a sensor, or a signal generated by a timer, and control the first light generating device to generate the first device light responsive to the obtaining of the at least one of the signal generated by user input at the user interface, the signal generated by the sensor, or the signal generated by the timer. Thus, the controlling of the first light generating device may hence be executed in response to user input at the user interface, in response to a sensor signal, and/or a time scheme or schedule. Possibly any other light generating device(s) in the light generating system may also be controlled in the same or similar manner. The term “timer” may refer to a clock and/or a predetermined time scheme or schedule. The sensor may be configured to sense one or more of a flow rate of the fluid, a conversion level of a chemical compound in the fluid, or a conversion rate of a chemical compound in the fluid.

The at least two centroid wavelengths may for example have a wavelength difference of at least 10 nm, or at least 30 nm. For example, the at least two centroid wavelengths may have a wavelength difference between 10 nm and 100 nm, or between 30 nm and 100 nm.

The first light generating device may be configured to generate, e.g., in an operational mode of the light generating system, the first device light such that it changes between the at least two centroid wavelengths with a changing frequency of at least 40 Hz, or at least 50 Hz. For example, the selected changing frequency by which the first device light changes between at least two centroid wavelengths may be at least 40 Hz, or at least 50 H. The selected changing frequency by which the first device light changes between at least two centroid wavelengths may for example be between 40 Hz and 100 Hz, or between 50 Hz and 100 Hz.

The first light generating device may for example comprise a first light source, which may be configured to generate first light source light. The photoreactor assembly may comprise an upconverter material, which may be arranged in relation to the first light source so as to receive the first light source light and which may be configured to convert at least part of the first light source light changing between the at least two centroid wavelengths into the first device light changing between the at least two centroid wavelengths.

The upconverter material may for example comprise one or more of an upconverter luminescent material (or “luminescent material”) and a frequency doubling material.

The first light source and the upconverter material may be arranged such that the first light source light comprises visible light or infrared light, and the first device light comprises or is constituted by ultraviolet light. Thus, UV light may be provided by the first light generating device as such or may be the result of an upconversion process. Hence, according to one or more embodiments of the present invention, a first light source configured to generate visible light or infrared light may be used in combination with upconverter material including one or more of a frequency doubling material or an upconversion luminescent material, such that the first light generating device provides UV light. The first light source and the upconverter material may be configured to generate the first device light having a wavelength in the wavelength range of 100 nm to 380 nm. Frequency doubling may also refer to triplicating a frequency or multiplications of one or more of doubling (now referring to 2× only) and triplicating.

According to one or more embodiments of the present invention, the “luminescent material” (or “upconverter luminescent material”) may refer to a material that can convert radiation into, e.g., visible light and/or infrared light. For instance, according to one or more embodiments of the present invention, the luminescent material may be able to convert one or more of UV light and blue light, into visible light. The luminescent material may according to one or more embodiments of the present invention convert radiation into IR light. Hence, upon excitation with radiation (or light), the luminescent material emits radiation (or light). In general, the luminescent material is an upconverter, i.e., light having a larger wavelength is converted into light having a smaller wavelength. In one or more embodiments of the present invention, downconverter material (e.g., luminescent material) might be used by which light having a smaller wavelength is converted into light having a larger wavelength.

According to one or more embodiments of the present invention, the term “luminescence” may refer to phosphorescence. According to one or more embodiments of the present invention, the term “luminescence” may also refer to fluorescence. Instead of the term “luminescence”, the term “emission” may be used. Likewise, the term “luminescent material” may, according to one or more embodiments of the present invention, refer to phosphorescence and/or fluorescence.

The term “luminescent material” may refer to a plurality of different luminescent materials. Examples of different luminescent materials are provided herein. Hence, the term “luminescent material” may according to one or more embodiments of the present invention refer to a luminescent material composition.

According to one or more embodiments of the present invention, luminescent materials may be selected from garnets and nitrides, especially doped with trivalent cerium or divalent europium, respectively. The term “nitride” may also refer to oxynitride or nitridosilicate, etc.

According to one or more embodiments of the present invention, the luminescent material may comprise a luminescent material of the type A₃B₅O₁₂:Ce, wherein A may comprise one or more of Y, La, Gd, Tb and Lu, especially (at least) one or more of Y, Gd, Tb and Lu, and wherein B may comprise one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, suitable luminescent materials may be cerium comprising garnet materials. Embodiments of garnets especially include A₃B₅O₁₂ garnets, wherein A comprises at least yttrium or lutetium and wherein B comprises at least aluminum. Such garnets may be doped with cerium (Ce), with praseodymium (Pr) or a combination of cerium and praseodymium; especially however with Ce. Especially, B comprises aluminum (Al), however, B may also partly comprise gallium (Ga) and/or scandium (Sc) and/or indium (In), especially up to about 20% of Al, more especially up to about 10% of Al (i.e. the B ions essentially consist of 90 or more mole % of Al and 10 or less mole % of one or more of Ga, Sc and In); B may especially comprise up to about 10% gallium. In another variant, B and O may at least partly be replaced by Si and N. The element A may especially be selected from the group consisting of yttrium (Y), gadolinium (Gd), terbium (Tb) and lutetium (Lu). Further, Gd and/or Tb are especially only present up to an amount of about 20% of A. In a specific embodiment, the garnet luminescent material comprises (Y₁₋ₓLuₓ)₃B₅O₁₂:Ce, wherein x is equal to or larger than 0 and equal to or smaller than 1. The term “:Ce”, indicates that part of the metal ions (i.e. in the garnets: part of the “A” ions) in the luminescent material is replaced by Ce. For instance, in the case of (Y₁₋ₓLuₓ)₃Al₅O₁₂:Ce, part of Y and/or Lu is replaced by Ce. This is known to the person skilled in the art. Ce will replace A in general for not more than 10%; in general, the Ce concentration will be in the range of 0.1 to 4%, especially 0.1 to 2% (relative to A). Assuming 1% Ce and 10% Y, the full correct formula could be (Y_{0.1}Lu_{0.89}Ce_{0.01})₃Al₅O₁₂. Ce in garnets is substantially or only in the trivalent state, as is known to the person skilled in the art.

According to one or more embodiments of the present invention, the luminescent material comprises A₃B₅O₁₂ wherein at maximum 10% of B—O may be replaced by Si—N.

According to one or more embodiments of the present invention, the luminescent material comprises (Yₓ₁₋ₓ₂₋ₓ₃A′ₓ₂Ceₓ₃)₃(Al_{y1-y2}B′_{y2})₅O₁₂, wherein x1+x2+x3=1, wherein x3>0, wherein 0<x2+x3≤0.2, wherein y1+y2=1, wherein 0≤y2≤0.2, wherein A′ comprises one or more elements selected from the group consisting of lanthanides, and wherein B′ comprises one or more elements selected from the group consisting of Ga, In and Sc. In embodiments, x3 is selected from the range of 0.001-0.1. In embodiments, x1>0, such as >0.2, or at least 0.8. Garnets with Y may provide suitable spectral power distributions.

According to one or more embodiments of the present invention, at maximum 10% of B—O may be replaced by Si—N. Here, B in B—O refers to one or more of Al, Ga, In and Sc (and O refers to oxygen); in embodiments B—O may refer to Al—O. In embodiments, x3 may be selected from the range of 0.001-0.04. Especially, such luminescent materials may have a suitable spectral distribution, have a relatively high efficiency, have a relatively high thermal stability, and allow a high color rendering index. Hence, in embodiments A may be selected from the group consisting of Lu and Gd. Alternatively or additionally, B may comprise Ga. Hence, in embodiments the luminescent material comprises (Yₓ₁₋ₓ₂₋ₓ₃(Lu,Gd)ₓ₂Ceₓ₃)₃(Al_{y1-y2}Ga_{y2})₅O₁₂, wherein Lu and/or Gd may be available. Even more especially, x3 is selected from the range of 0.001-0.1, wherein 0<x2+x3≤0.1, and wherein 0≤y2≤0.1. Further, in specific embodiments, at maximum 1% of B—O may be replaced by Si—N. Here, the percentage refers to moles (as known in the art); see e.g. also EP3149108. In yet other embodiments, the luminescent material comprises (Yₓ₁₋ₓ₃Ceₓ₃)₃Al₅O₁₂, wherein x1+x3=1, and wherein 0<x3≤0.2, such as 0.001-0.1.

According to one or more embodiments of the present invention, the first light generating device may only use or include luminescent materials selected from the type of cerium comprising garnets. In embodiments, the first light generating device may include a single type of luminescent materials, such as (Yₓ₁₋ₓ₂₋ₓ₃A′ₓ₂Ceₓ₃)₃(Al_{y1-y2}B′_{y2})₅O₁₂. Hence, in embodiments the first light generating device comprises luminescent material, wherein at least 85 weight %, even more especially at least about 90 wt. %, such as yet even more especially at least about 95 weight % of the luminescent material comprises (Yₓ₁₋ₓ₂₋ₓ₃A′ₓ₂Ceₓ₃)₃(Al_{y1-y2}B′_{y2})₅O₁₂. Here, wherein A′ comprises one or more elements selected from the group consisting of lanthanides, and wherein B′ comprises one or more elements selected from the group consisting of Ga, In and Sc, wherein x1+x2+x3=1, wherein x3>0, wherein 0<x2+x3≤0.2, wherein y1+y2=1, wherein 0≤y2≤0.2. x3 may be selected from the range of 0.001-0.1. In embodiments, x2=0. Alternatively or additionally, in embodiments y2=0.

According to one or more embodiments of the present invention, A may comprise at least Y, and B may comprise at least Al.

Therefore, according to one or more embodiments of the present invention, the luminescent material may comprise a luminescent material of the type A₃B₅O₁₂:Ce, wherein A comprises one or more of Y, La, Gd, Tb and Lu, and wherein B comprises one or more of Al, Ga, In and Sc.

Alternatively or additionally, the luminescent material may comprises a luminescent material of the type A₃Si₆N₁₁:Ce³⁺, wherein A comprises one or more of Y, La, Gd, Tb and Lu, such as in embodiments one or more of La and Y.

According to one or more embodiments of the present invention, the luminescent material may alternatively or additionally comprise one or more of M₂Si₅N₈:Eu²⁺ and/or MAlSiN₃:Eu²⁺ and/or Ca₂AlSi₃O₂N₅:Eu²⁺, etc., wherein M comprises one or more of Ba, Sr and Ca, especially in embodiments at least Sr. Hence, in embodiments, the luminescent may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba. The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca). Likewise, the material (Ba, Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca). Eu in the above indicated luminescent materials is substantially or only in the divalent state, as is known to the person skilled in the art.

According to one or more embodiments of the present invention, a red luminescent material may comprise one or more materials selected from the group consisting of (Ba,Sr,Ca)S:Eu, (Ba,Sr,Ca)AlSiN₃:Eu and (Ba,Sr,Ca)₂Si₅N₈:Eu. In these compounds, europium (Eu) is substantially or only divalent, and replaces one or more of the indicated divalent cations. In general, Eu will not be present in amounts larger than 10% of the cation; its presence will especially be in the range of about 0.5 to 10%, more especially in the range of about 0.5 to 5% relative to the cation(s) it replaces. The term “:Eu”, indicates that part of the metal ions is replaced by Eu (in these examples by Eu²⁺). For instance, assuming 2% Eu in CaAlSiN₃:Eu, the correct formula could be (Ca_{0.98}Eu_{0.02})AlSiN₃. Divalent europium will in general replace divalent cations, such as the above divalent alkaline earth cations, especially Ca, Sr or Ba.

The material (Ba,Sr,Ca)S:Eu can also be indicated as MS:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Further, the material (Ba,Sr,Ca)₂Si₅N₈:Eu can also be indicated as M₂Si₅N₈:Eu, wherein M is one or more elements selected from the group consisting of barium (Ba), strontium (Sr) and calcium (Ca); especially, M comprises in this compound Sr and/or Ba. In a further specific embodiment, M consists of Sr and/or Ba (not taking into account the presence of Eu), especially 50 to 100%, more especially 50 to 90% Ba and 50 to 0%, especially 50 to 10% Sr, such as Ba_{1.5}Sr_{0.5}Si₅N₈:Eu (i.e. 75% Ba; 25% Sr). Here, Eu is introduced and replaces at least part of M, i.e. one or more of Ba, Sr, and Ca).

Likewise, the material (Ba,Sr,Ca)AlSiN₃:Eu can also be indicated as MAlSiN₃:Eu, wherein M is one or more elements selected from the group consisting of barium (Ba), strontium (Sr) and calcium (Ca); especially, M comprises in this compound calcium or strontium, or calcium and strontium, more especially calcium. Here, Eu is introduced and replaces at least part of M (i.e. one or more of Ba, Sr, and Ca).

Eu in the above indicated luminescent materials is substantially or only in the divalent state, as is known to the person skilled in the art.

Blue luminescent materials may comprise YSO (Y₂SiO₅:Ce³⁺), or similar compounds, or BAM (BaMgAl₁₀O₁₇:Eu²⁺), or similar compounds.

The term “luminescent material” herein especially relates to inorganic luminescent materials.

Instead of the term “luminescent material” the term “phosphor” may be used. These terms are known to the person skilled in the art.

Alternatively or additionally, other type or types of luminescent materials may be used. For instance, quantum dots and/or organic dyes may be used and may optionally be embedded in transmissive matrices like e.g. polymers, like PMMA, or polysiloxanes, etc, etc.

Quantum dots are small crystals of semiconducting material generally having a width or diameter of only a few nanometers. When excited by incident light, a quantum dot emits light of a color determined by the size and material of the crystal. Light of a particular color can therefore be produced by adapting the size of the dots. Most known quantum dots with emission in the visible range are based on cadmium selenide (CdSe) with a shell such as cadmium sulfide (CdS) and zinc sulfide (ZnS). Cadmium free quantum dots such as indium phosphide (InP), and copper indium sulfide (CuInS₂) and/or silver indium sulfide (AgInS₂) can also be used. Quantum dots show very narrow emission band and thus they show saturated colors. Furthermore the emission color can easily be tuned by adapting the size of the quantum dots. Any type of quantum dot known in the art may be used in the present invention. However, it may be preferred for reasons of environmental safety and concern to use cadmium-free quantum dots or at least quantum dots having a very low cadmium content.

Instead of quantum dots or in addition to quantum dots, also other quantum confinement structures may be used. The term “quantum confinement structures” should, in the context of the present application, be understood as e.g. quantum wells, quantum dots, quantum rods, tripods, tetrapods, or nano-wires, etcetera.

Organic phosphors can be used as well. Examples of suitable organic phosphor materials are organic luminescent materials based on perylene derivatives, for example compounds sold under the name Lumogen® by BASF. Examples of suitable compounds include, but are not limited to, Lumogen® Red F305, Lumogen® Orange F240, Lumogen® Yellow F083, and Lumogen® F170.

Different luminescent materials may have different spectral power distributions of the respective luminescent material light. Alternatively or additionally, such different luminescent materials may especially have different color points (or dominant wavelengths).

Another or other types of luminescent materials may also be possible. Hence, according to one or more embodiments of the present invention, the luminescent material may be selected from the group of divalent europium containing nitrides, divalent europium containing oxynitrides, divalent europium containing silicates, cerium comprising garnets, and quantum structures. Quantum structures may, e.g., comprise quantum dots or quantum rods (or other quantum type particles). Quantum structures may also comprise quantum wells. Quantum structures may also comprise photonic crystals.

The photoreactor assembly may comprise a second light generating device configured to generate second device light. The second light generating device may be configured to generate the second device light so that it comprises one or more of UV light, visible light, and IR light. The second light generating device may for example comprise one or more of a laser and a superluminescent diode. The first device light and the second device light may have different spectral power distributions. The light generating system may be configured to generate system light comprising the first device light and the second device light. The reactor chamber may be configured in a light-receiving relationship with the first light generating device and the second light generating device such that the system light irradiates at least a part of the fluid. The second light generating device may be controllable at least with respect to the wavelength of the second device light. To that end, the second light generating device may comprise or be constituted by a wavelength variable light generating device (e.g., a single wavelength variable light generating device). The second light generating device (or, e.g., the wavelength variable light generating device thereof) may be configured to generate, e.g., in a (the) operational mode of the light generating system, the second device light such that it changes between at least two centroid wavelengths having a wavelength difference of at least 10 nm with a selected changing frequency.

It is to be understood that the second light generating device may be configured similarly to or in the same way as the first light generating device at least with respect to generation of light. In particular, each of the implementations of the first light generating device disclosed herein may be realized in the same way or similarly for the second light generating device. In other words, all embodiments of the first light generating device disclosed herein are applicable in the same way or similarly for the second light generating device. Controlling of the second light generating device as described herein may refer to controlling the wavelength-variable light generating device of the second light generating device.

The first light generating device may be configured to generate the first device light having a centroid wavelength in a first wavelength range and wherein the second light generating device is configured to generate the second device light having a centroid wavelength in a second wavelength range different from the first wavelength range.

The control system may be configured to control the first light generating device (and/or the second light generating device) by pulse width modulation. The control system may for example be configured to control a spectral power distribution of the light emitted by the light generating system, e.g., in an (the) operational mode, by controlling a duty cycle of the first device light (and/or a duty cycle of the second device light).

The fluid may be subjected to a process in the reaction chamber involving one or more chemical reactions in the fluid. Facilitation of the one or more chemical reactions may be governed by at least wavelength of the first device light with which the fluid is treated. For the one or more chemical reactions in the fluid, there may be desired wavelength range within which the wavelength of the first device light with which the fluid is treated is desired to be. In alternative or in addition, facilitation of the one or more chemical reactions may be governed by intensity of the first device light with which the fluid is treated. For the one or more chemical reactions in the fluid, there may be desired intensity range within which the intensity of the first device light with which the fluid is treated is desired to be.

The photoreactor may for example comprise a spinning disk reactor. The spinning disk reactor may comprise a disk (or “spinning disk”, or “reactor disk”, or “rotatable disk”) which may be at least partly configured in the reaction chamber. Thus, according to one or more embodiments of the present invention, a photoreactor assembly may be provided comprising a spinning disk reactor. Such a photoreactor assembly may be able to treat a fluid in the reactor chamber with the light source radiation with relatively high mixing performance and relatively high pressure. Spinning disk reactors are a type of chemical reactor which may be used because the relatively small area between a fast rotating disc and the reactor wall may result in very high mixing performance. High gaseous or liquid pressures occur for chemical processes in such spinning disk reactors. The relatively high mixing performance and relatively high pressure obtainable with the photoreactor comprising or being constituted by a spinning disk reactor may result in a relatively high efficiency of any chemical reaction in a process to which the fluid may be subjected to in the reaction chamber.

The first light generating device may for example comprise a group, e.g., an array, of at least ten lasers. In alternative or in addition, the first light generating device may for example comprise a group, e.g., an array, of at least ten superluminescent diodes.

As mentioned, the control system is configured to obtain at least one of a signal generated by user input at a user interface, a signal generated by a sensor, or a signal generated by a timer, and control the first light generating device to generate the first device light responsive to the obtaining of the at least one of the signal generated by user input at the user interface, the signal generated by the sensor, or the signal generated by the timer. The photoreactor assembly may comprise one or more of a (the) sensor, a (the) user interface or a (the) timer. For example, the photoreactor assembly may comprise a sensor, which may be configured to sense one or more of a flow rate of the fluid (e.g., in the reaction chamber), a conversion level of a chemical compound in the fluid (e.g., in the reaction chamber), or a conversion rate of a chemical compound in the fluid (e.g., in the reaction chamber).

As indicated above, a photoreactor assembly is provided comprising a photoreactor, e.g., a photochemical reactor. The term “reactor” may especially relate to a (photo) chemical reactor. The term may essentially relate to an enclosed (reactor) chamber in which a (photochemical) reaction may take place. The (photochemical) reaction may take place due to irradiation of a fluid with the light source radiation. In the present application, the terms “photoreactor” and “photochemical reactor” may be used interchangeably with no loss of generality.

The photochemical reactor may comprise a reactor chamber further comprising a flow reactor system. The reactor chamber and a light generating system chamber, in which at least the first light generating device and any other light generating device and related equipment of the light generating system may be included, may be configured in optical contact. Optical contact may refer to the transfer of light (or radiation) between two conformal surfaces, such as between the reactor chamber and the light generating system chamber. Hence, radiation of the light source(s) including the first light generating device may propagate via the light generating system chamber into the flow reactor system (comprised by the reactor chamber). As indicated above, the reactor chamber and the light generating system chamber may comprise light transmissive materials. The light transmissive materials of the reactor chamber and light generating system chamber may be the same or may be different. When the reactor chamber and the light generating system chamber are part of a monolithic body, they will in general comprise essentially the same light transmissive materials. Only the light generating system chamber may comprise light transmissive material.

The flow reactor system may comprise a reactor channel, through which the fluid may flow. The flow reactor system may be configured to react one or more reactor fluid(s) within flow reactor cells in the reactor channel or comprised by the reactor channel. One or more chemicals that may flow through the flow reactor cells may (also) be reacted with the light source radiation irradiated on the one or more chemicals. The flow reactor system may be configured for hosting the (reactor) fluid to be treated, especially with light source radiation (e.g., the first device light). The fluid may be transported through the flow reactor system and at least part of the flow reactor system may be irradiated with the light source radiation.

The flow reactor system may comprise one or more channels and optionally one or more reaction chambers in fluid contact with the one or more channels. The light source radiation may be provided to at least part of the one or more channels, or, when one or more reaction chambers are available, alternatively or additionally to the one or more reaction chambers. A reaction chamber may comprise a flow reactor cell. However, the reactor chamber may also be channel, or a part of the channel. Hence, the reactor chamber may be channel, having essentially the same cross-sectional dimensions as an upstream channel part and a downstream channel part. However, such as in the case of a spinning disk reactor, the reactor chamber may have cross-sectional dimensions different from an upstream channel (part) and/or a downstream channel (part).

The (reactor) fluid may comprise one or more of a liquid and a gas. The term “fluid” may also refer to a combination of two or more different fluids. When the reactor fluid comprises a liquid, the liquid may comprise one liquid or two or more different liquids.

The liquid may in embodiments also comprise particulate material. When the (reactor) fluid comprises a gas, the gas may comprise one type of gas or two or more types of different gasses. The fluid may comprise particulate catalyst material or may comprise a homogenous catalyst, but may in other embodiments also comprise no catalyst. The fluid may comprise an emulsion.

The reactor fluid may comprise at least one or more reactants. Reactants are chemical substances that may take part in the (photo) chemical reaction. The one or more reactants may undergo a chemical change as the (photo) chemical reaction takes place to provide a chemical product. When the (photo) chemical reaction has completed, at least part of the one or more reactants may have become the chemical product. Especially, the reactor fluid may comprise at least two or more reactants, which during the (photo) chemical reaction react with one or more of the other reactants to provide at least one or more chemical product.

The photochemical reactor may comprise a catalyst. The catalyst is a chemical substance that does not undergo a chemical change as the (photo) chemical reaction takes place. The catalyst may in embodiments improve the reaction rate of the (photo) chemical reaction. The catalyst may in specific embodiments facilitate the (photo) chemical reaction. As the catalyst does not undergo a chemical change, it may be used over multiple (photo) chemical reactions. The catalyst may be immobilized on part of the reactor chamber and/or on the disk. Chemical reactions in reactors are as such known to the person skilled in the art.

The photochemical reactor may comprise a spinning disk reactor. The spinning disk reactor may comprise a rotatable spinning disk. Such spinning disk may consist of two main parts: a wheel part (or: “wheel”) and an axle part (or: “axle”). The wheel part of the spinning disk may be rotatable around a fixed axis defined by the axle part. The axle part may be connected to a further mechanical system comprised by a rotor. As the mechanical system comprised by the rotor rotates, it may drive the rotation of the axle and wheel parts of the spinning disk. The spinning disk may be at least partly configured in the reaction chamber. At least the wheel part of the spinning disk may be configured entirely in the reaction chamber. Further, the spinning disk comprising the wheel part and axle part may be entirely configured within the reaction chamber. In other embodiments, at least part of the axle part may be configured outside of the reaction chamber. Moreover, the axle part may be configured entirely outside of the reaction chamber.

The rotational speed of the spinning disk may in embodiments be controlled. In embodiments, the spinning disk may be under on/off control, with a single rotational speed being available when the spinning disk is turned on. The spinning disk may be able to operate at multiple speed settings when the spinning disk is turned on. The rotational speed of the spinning disk may increase or decrease in gradual advancement when the spinning disk is turned on. The spinning disk may be turned on for at least part of the duration of the (photo) chemical reaction. The spinning disk may be turned on for the entire duration of the (photo) chemical reaction. The spinning disk may be turned on for a specific duration during the (photo) chemical reaction and turned off after that duration. Further, the spinning disk may be turned on and off at least twice or more during the (photo) chemical reaction. The spinning disk may have at least one or more rotational speeds during the (photo) chemical reaction. By the rotation of the spinning disk, especially the wheel part of the spinning disk, the spinning disk may exert a force on the reactor chamber and/or the fluid in the reactor chamber. This force may result in (i) mixing the first fluid with high efficiency and (ii) increasing the reactor chamber pressure. Mixing the first fluid with high efficiency may result in improved reaction rate and may hence facilitate the reaction to reach equilibrium faster. Increasing the reactor chamber pressure may likewise result in an improved reaction rate and may hence facilitate the reaction to reach equilibrium faster.

The photochemical reactor may comprise a flow reactor. The flow reactor may comprise a reactor channel, through which the fluid may be flowing. The flow reactor may be configured to react one or more rector fluid(s) within flow reactor cells in the reactor channel or comprised by the reactor channel. The one or more chemicals which may be flowing through the flow reactor cells may (also) be reacted with the light source light irradiated on the one or more chemicals. The flow reactor may be configured for hosting the (reactor) fluid to be treated.

Within the context of a photochemical reactor, the photochemical reaction of the fluid may be driven by exposure to light generated by the light generating system or first light generating device. Mixing the fluid with high efficiency may result in a more even dispersion of the various compounds in the first fluid and hence more even exposure to the light, especially when light may not penetrate evenly throughout the reactor chamber. Hence the mixing by the spinning disk may result in an improved reaction rate.

The reaction driven by the photochemical reactor may comprise a multistep reaction. Such a multistep reaction may comprise at least two or more (photo) chemical reactions. In such cases, at least one or more of the two or more (photo) chemical reactions may be a photochemical reaction. If one or more of the (photo) chemical reactions are not a photochemical reaction, the increased pressure in the reactor chamber by the spinning disk may improve the reaction rate of the one or more reaction steps that is not a photochemical reaction.

As mentioned, the first light generating device may comprise one or more of a laser and a superluminescent diode. It is contemplated that in addition or in alternative to superluminescent diode another or other types of semiconductor light sources could be used, such as light-emitting diodes (LEDs). The term “laser” encompasses any laser-based light source but especially a laser.

Some types of lasers or laser-based light sources may not be wavelength tunable. A laser or laser-based light source may be combined with an upconverter in order to arrive at shorter (laser) wavelengths. For instance, with some (trivalent) rare earth ions upconversion may be obtained or with non-linear crystals upconversion can be obtained. Alternatively, a laser or laser-based light source may be combined with a downconverter, such as a dye laser, to arrive at longer (laser) wavelengths.

The laser may for example comprise or be constituted by one or more vertical cavity surface emitting laser (VCSEL) devices. VCSELs may have the capability of controlling wavelength of the light emitted by the VCSEL. A VCSEL is as such known in the art and may especially be a type of semiconductor laser diode with laser beam emission perpendicular from the top surface, contrary to edge-emitting semiconductor lasers (also in-plane lasers) which emit from surfaces formed by cleaving the individual chip out of a wafer. VCSELs may be tunable in emission wavelength, as known in the art. For instance, Dupont et al., Applied Physics Letters 98 (16): 161105-161105-3, DOI: 10.1063/1.3569591, or Wendi Chang et al., Applied Physics Letters 105 (7): 073303, DOI: 10.1063/1.4893758, or Thor Ansbaek, IEEE Journal of Selected Topics in Quantum Electronics 19 (4): 1702306-1702306, DOI: 10.1109/JSTQE.2013.2257164, or C. J. Chang-Hasnain, IEEE Journal of Selected Topics in Quantum Electronics (Volume: 6, Issue: 6, November-December 2000), DOI: 10.1109/2944.902146, or Kögel et al., IEEE Sensors Journal, December 2007, volume 7, no. 11, pages 1483-1489, or Jayaraman, et al., Electron Lett. 2012 Jul. 5; 48 (14): 867-869. doi: 10.1049/el.2012.1552, all of which documents are incorporated herein by reference, describe emission wavelength tunable VCSELs. Especially, with varying electrical voltage, the spectral power distribution of the VCSEL may vary. Hence, the term “VCSEL” may thus especially refer herein to a tunable VCSEL, as known in the art. Such tunable VCSELs may be based on MEMS technology. Such (tunable) VCSEL may also be indicated as “MEMS VCSEL”. Therefore, according to one or more embodiments of the present invention, the laser diode may comprise a VCSEL that has single-mode light emission and a long coherence length. The wavelength sweep may be implemented using a micro-electro-mechanical system (MEMS) to change the length of the laser cavity by which a stable and rapid wavelength sweep results.

A laser-based light source or a laser may be configured to generate laser light source light having one or more wavelengths in the UV light wavelength range, visible light wavelength range, and/or IR light wavelength range, especially having a wavelength selected from the spectral wavelength range of 200 nm-2000 nm, such as 300 nm-1500 nm. The term “laser” especially refers to a device that emits light through a process of optical amplification based on the stimulated emission of electromagnetic radiation.

In one or more embodiments of the present invention, the term “laser” may refer to a solid-state laser. In one or more embodiments of the present invention, the terms “laser” or “laser-based light source”, or similar terms, may refer to a laser diode (or diode laser).

In one or more embodiments of the present invention, the terms “laser” or “laser-based light source”, or similar terms, may refer to one or more of cerium doped lithium strontium (or calcium) aluminum fluoride (Ce:LiSAF, Ce:LiCAF), chromium doped chrysoberyl (alexandrite) laser, chromium ZnSe (Cr:ZnSe) laser, divalent samarium doped calcium fluoride (Sm:CaF₂) laser, Er:YAG laser, erbium doped and erbium-ytterbium codoped glass lasers, F-Center laser, holmium YAG (Ho:YAG) laser, Nd:YAG laser, NdCrYAG laser, neodymium doped yttrium calcium oxoborate Nd:YCa₄O(BO₃)₃ or Nd:YCOB, neodymium doped yttrium orthovanadate (Nd:YVO₄) laser, neodymium glass (Nd:glass) laser, neodymium YLF (Nd:YLF) solid-state laser, promethium 147 doped phosphate glass (147Pm³⁺:glass) solid-state laser, ruby laser (Al₂O₃:Cr³⁺), thulium YAG (Tm:YAG) laser, titanium sapphire (Ti:sapphire; Al₂O₃:Ti³⁺) laser, trivalent uranium doped calcium fluoride (U:CaF₂) solid-state laser, Ytterbium doped glass laser (rod, plate/chip, and fiber), Ytterbium YAG (Yb:YAG) laser, Yb₂O₃ (glass or ceramics) laser, etc.

For instance, including second and third harmonic generation embodiments, the laser or laser-based light source may comprise one or more of an F center laser, an yttrium orthovanadate (Nd:YVO₄) laser, a promethium 147 doped phosphate glass (147Pm³⁺:glass), and a titanium sapphire (Ti:sapphire; Al₂O₃:Ti³⁺) laser. For instance, considering second and third harmonic generation, such light sources may be used to generate blue light.

According to one or more embodiments of the present invention, the terms “laser” or “laser-based light source”, or similar terms, may refer to one or more of a semiconductor laser diodes, such as GaN, InGaN, AlGaInP, AlGaAs, InGaAsP, lead salt, vertical cavity surface emitting laser (VCSEL), quantum cascade laser, hybrid silicon laser, etc.

The term “laser” or “laser-based light source” (or “laser light source”) may refer to a plurality of (different or identical) laser light sources. According to one or more embodiments of the present invention, the term “laser light source” may refer to a plurality N of (identical) laser light sources, where, for example, N=2, or more. According to one or more embodiments of the present invention, N may be at least 5, such as at least 8. In this way, a higher brightness may be obtained. According to one or more embodiments of the present invention, laser light sources may be arranged in a laser bank. A laser bank may, in accordance with one or more embodiments of the present invention, comprise heat sinking and/or optics, e.g., a lens, to collimate the laser light. Hence, according to one or more embodiments of the present invention, lasers in a laser bank may share the same optics.

The laser light source may be configured to generate laser light source light (or “laser light”). The first device light may essentially consist of the laser light source light. The first device light may comprise laser light source light of two or more (different or identical) laser light sources. For instance, the laser light source light of two or more (different or identical) laser light sources may be coupled into a light guide, to provide a single beam of light comprising the laser light source light of the two or more (different or identical) laser light sources. According to one or more embodiments of the present invention, the first device light may thus be collimated light. According to one or more embodiments of the present invention, the first device light may be (collimated) laser light source light.

The laser light source light may in embodiments comprise one or more bands, having bandwidths as known for lasers. In specific embodiments, the band(s) may be relatively sharp line(s), such as having full width half maximum (FWHM) in the range of less than 20 nm at room temperature, such as equal to or less than 10 nm. Hence, the light source light has a spectral power distribution (intensity on an energy scale as function of the wavelength) which may comprise one or more (narrow) bands.

The first device light may include beams such as focused or collimated beams of (laser) light source light. The term “focused” may refer to converging to a small spot. This small spot may be at the discrete converter region, or (slightly) upstream thereof or (slightly) downstream thereof. Especially, focusing and/or collimation may be such that the cross-sectional shape (perpendicular to the optical axis) of the beam at the discrete converter region (at the side face) is essentially not larger than the cross-section shape (perpendicular to the optical axis) of the discrete converter region (where the light source light irradiates the discrete converter region). Focusing may be executed with one or more optics, like (focusing) lenses. Especially, two lenses may be applied to focus the laser light source light. Collimation may be executed with one or more (other) optics, like collimation elements, such as lenses and/or parabolic mirrors. According to one or more embodiments of the present invention, the beam of (laser) light source light may be relatively highly collimated, such as, for example, ≤2° (FWHM), more especially ≤1° (FWHM), most especially ≤0.5° (FWHM). Hence, ≤2° (FWHM) may be considered (highly) collimated (laser) light source light. Optics may be used to provide a relatively high collimation.

According to one or more embodiments of the present invention, the terms “laser” or “laser-based light source”, or similar terms, may refer to a solid state laser for example based on a crystalline or glass body dopes with ions, such as transition metal ions and/or lanthanide ions, to a fiber laser, to a photonic crystal laser, and/or to a semiconductor laser, such as, e.g., a VCSEL, etc.

The first device light may comprise UV light. According to one or more embodiments of the present invention, the first light generating device may be configured to generate first device light having a wavelength selected from the wavelength range of 100 nm to 380 nm. Light in a wavelength range of 100 nm to 380 nm may have a disinfection function as it may be detrimental for bacteria and/or viruses.

As mentioned, is contemplated that in addition or in alternative to superluminescent diode, another or other types of semiconductor light sources could be used, such as light-emitting diodes (LEDs). A LED may for example include or be constituted by an inorganic LED and/or an organic LED (OLED). Examples of LEDs include semiconductor, organic, or polymer/polymeric LEDs, optically pumped phosphor coated LEDs, optically pumped nano-crystal LEDs or any other similar devices as would be readily understood by a person skilled in the art. For example, the term LED can encompass a bare LED die arranged in a housing, which may be referred to as a LED package. According to another example, the term LED can encompass a Chip Scale Package (CSP) LED, which may comprise a LED die directly attached to a substrate such as a PCB, and not via a sub-mount. The term LED can for example encompass a laser diode, because a laser diode is a diode which emits light. In recent years the output of LEDs, both direct LEDs with dominant wavelengths ranging for instance from ultraviolet-C to infrared wavelengths, and phosphor-converted LEDs, has increased drastically, making them interesting candidates for light sources for photochemistry. High fluxes can be obtained from small surfaces, especially if the LEDs can be kept at a low temperature.

The control system may comprise one or more controllers, control units, control devices, etc., each or any of which for example may include or be constituted by any suitable central processing unit (CPU), microcontroller, digital signal processor (DSP), Application Specific Integrated Circuit (ASIC), Field Programmable Gate Array (FPGA), etc., or any combination thereof. The one or more controllers, control units, control devices, etc., may optionally be capable of executing software instructions stored in a computer program product, e.g., in the form of a memory. The memory may for example be any combination of read and write memory (RAM) and read only memory (ROM). The memory may comprise persistent storage, which for example can be a magnetic memory, an optical memory, a solid state memory or a remotely mounted memory, or any combination thereof.

The one or more controllers, control units, control devices, etc., may for example comprise driver circuitry for controlling supply of power to the light generating system such as to the first light generating device and/or for controlling operation of the light generating system, e.g., the first light generating device and/or any other light generating device which may be comprised in the light generating system. The driver circuitry may for example comprise driver circuitry configured to drive (or control operation of) the first light generating device. The one or more controllers, control units, control devices, etc., may be configured to control operation of the first light generating device and/or any other light generating device which may be comprised in the light generating system for example by way of transmitting at least one control signal or control message or the like to the first light generating device and/or any other light generating device which may be comprised in the light generating system.

Further objects and advantages of the present invention are described in the following by means of exemplifying embodiments. It is noted that the present invention relates to all possible combinations of features recited in the claims. Further features of, and advantages with, the present invention will become apparent when studying the appended claims and the description herein. Those skilled in the art realize that different features of the present invention can be combined to create embodiments other than those described herein.

### BRIEF DESCRIPTION OF THE DRAWINGS

Exemplifying embodiments of the invention will be described below with reference to the accompanying drawings.

FIGS. 1 and 2 are schematic, in part sectional, side views of photoreactor assemblies according to respective embodiments of the present invention.

FIG. 3 is a schematic view of a first light generating device of a photoreactor assembly in accordance with an embodiment of the present invention.

FIG. 4 schematically depicts intensity versus wavelength of light generated by a possible first light generating device comprising a wavelength tunable vertical cavity surface emitting laser (VCSEL).

FIG. 5 is a schematic, in part sectional, view of a light generating system of a photoreactor assembly in accordance with an embodiment of the present invention.

FIG. 6 schematically depicts intensity versus wavelength relating to light generated by, e.g., the first light generating device illustrated in FIG. 5.

FIG. 7 is a schematic, in part sectional, view of a light generating system of a photoreactor assembly in accordance with an embodiment of the present invention.

FIG. 8 is schematic views of a first light generating device and a second light generating device of a photoreactor assembly in accordance with embodiments of the present invention.

FIG. 9 schematically depicts intensity versus wavelength relating to light generated by, e.g., the first light generating device and the second light generating device illustrated in FIG. 8.

FIG. 10 schematically illustrates examples of pulse width modulation.

All the figures are schematic, not necessarily to scale, and generally only show parts which are necessary in order to elucidate embodiments of the present invention, wherein other parts may be omitted or merely suggested.

### DESCRIPTION WITH REFERENCE TO THE DRAWINGS

The present invention will now be described hereinafter with reference to the accompanying drawings, in which exemplifying embodiments of the present invention are shown. The present invention may, however, be embodied in many different forms and should not be construed as limited to the embodiments of the present invention set forth herein; rather, these embodiments of the present invention are provided by way of example so that this disclosure will convey the scope of the invention to those skilled in the art. In the drawings, identical reference numerals denote the same or similar components having a same or similar function, unless specifically stated otherwise.

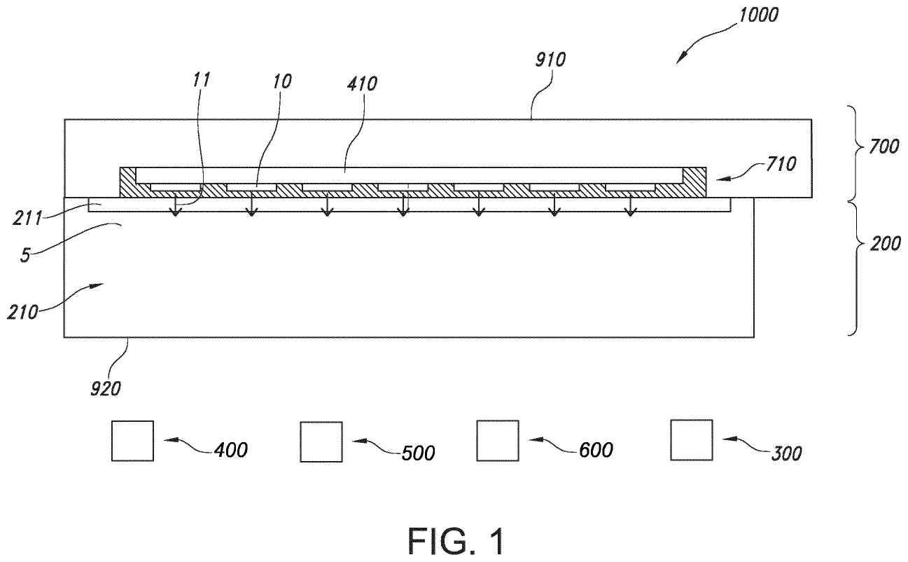

FIG. 1 is a schematic, in part sectional, side view of a photoreactor assembly 1000 according to an embodiment of the present invention. The photoreactor assembly 1000 illustrated in FIG. 1 comprises a light generating system 700, a photoreactor 200, and a control system 300.

The light generating system 700 comprises a least one first light generating device 10. In accordance with the embodiment of the present invention illustrated in FIG. 1, the light generating system 700 comprises a plurality of first light generating devices 10. Only one of the first light generating devices 10 is indicated by reference numeral. It is to be understood that the number of first light generating devices 10 depicted in FIG. 1 is according to an example, and that the light generating system 700 could comprise, in principle, any number of first light generating devices 10.

In accordance with the embodiment of the present invention illustrated in FIG. 1, each of the first light generating devices 10 is configured to generate first device light, schematically indicated at 11 for one of the depicted first light generating devices 10, comprising one or more of ultraviolet light, visible light, and infrared light. Each of the first light generating devices 10 may comprise one or more of a laser and a superluminescent diode.

The photoreactor 200 comprises a reactor chamber 210, which is configured to host a fluid 5 to be treated with the first device light 11. As illustrated in FIG. 1, the reactor chamber 210 is configured in a light-receiving relationship with the first light generating devices 10 such that the first device light 11 irradiates at least a part of the fluid 5.

In accordance with the embodiment of the present invention illustrated in FIG. 1, the photoreactor 200 may comprise a light transmissive window 211 that is transmissive for at least the first device light 11. The light transmissive window 211 separates the first light generating devices 10 from the reactor chamber 210. The first light generating devices 10 are configured to irradiate at least part of the reactor chamber 210 via the light transmissive window 211. Thereby, the first device light 11 irradiates at least a part of the fluid 5. The light transmissive window 211 may for example comprise a light transmissive material selected from the group of quartz, sapphire, borosilicate glass, sodalime glass, mineral glass, laminated glass, coated glass.

Although not shown in FIG. 1, the photoreactor assembly 1000 may comprise one or more inlets in the reactor chamber 210 permitting the fluid 5 to be introduced into the reactor chamber 210 and one or more outlets in the reactor chamber 210 permitting the fluid 5 to exit the reactor chamber 210. One or more of the one or more inlets and the one or more outlets may be provided with a controllable fluid flow restriction such as a valve for controlling fluid flow. The photoreactor assembly 1000 may be arranged to permit a flow of fluid through the reactor chamber, e.g., from the one or more inlets to the one or more outlets of the reactor chamber 210.

Further in accordance with the embodiment of the present invention illustrated in FIG. 1, the photoreactor assembly 1000 may comprise a light generating device support 410, which may be configured to support the first light generating devices 10 and on which the first light generating devices 10 may be arranged, as illustrated in FIG. 1.

Further in accordance with the embodiment of the present invention illustrated in FIG. 1, the photoreactor assembly 1000 may comprise a light generating system housing 910 and a photoreactor housing 920. According to the illustrated embodiment of the present invention, the light generating system housing 910 in part encloses a light generating system chamber 710, in which the light generating device source support 410 and the first light generating devices 10 are included. Further, the photoreactor housing 920 in part encloses the reactor chamber 210, and the light transmissive window 211 separates the light generating system 710 from the reactor chamber 210.

In accordance with the embodiment of the present invention illustrated in FIG. 1, each of the first light generating devices 10 is controllable at least with respect to the wavelength of the first device light 11 and configured to generate the first device light 11 such that it changes between at least two centroid wavelengths having a wavelength difference of at least 10 nm with a selected changing frequency.

In accordance with the embodiment of the present invention illustrated in FIG. 1, each (or any) of the first light generating devices 10 may be constituted by a wavelength-variable light generating device that is controllable at least with respect to the wavelength of the first device light 11 and configured to generate the first device light 11 such that it changes between at least two centroid wavelengths having a wavelength difference of at least 10 nm with a selected changing frequency.

The control system 300 is configured to obtain at least one of a signal generated by user input at a user interface, a signal generated by a sensor, or a signal generated by a timer. To that end, the control system 300 may be connected with the user interface, the sensor and the timer, respectively, in wired and/or wireless fashion, such as, for example, using any wired and/or wireless communication means or techniques as known in the art.

The control system 300 is configured to control the first light generating devices 10 (e.g., control each of the first light generating devices 10) to generate the first device light 11 responsive to the obtaining of the at least one of the signal generated by user input at the user interface, the signal generated by the sensor, or the signal generated by the timer. To that end, the control system 300 may be connected with light generating system 700, e.g., connected with the first light generating devices 10 individually, in wired and/or wireless fashion, such as, for example, using any wired and/or wireless communication means or techniques as known in the art. The control system 300 may be configured to control operation of the first light generating devices 10 and/or any other light generating device which may be comprised in the light generating system 700 for example by way of transmitting at least one control signal or control message or the like to the first light generating devices 10 and/or any other light generating device which may be comprised in the light generating system 700.

The controlling of the first light generating device(s) 10, and possibly any other light generating device(s) in the light generating system 700, may hence be executed in response to user input at the user interface, in response to a sensor signal, and/or a time scheme or schedule. The term “timer” may refer to a clock and/or a predetermined time scheme or schedule.

The sensor signal may be provided by a sensor, schematically indicated at 400, which may possibly be included in the photoreactor assembly 1000. The sensor 400 may be configured to sense one or more of a flow rate of the fluid 5, a conversion level of a chemical compound in the fluid 5, or a conversion rate of a chemical compound in the fluid 5.

The photoreactor assembly 1000 may possibly include a (the) user interface and/or the timer, schematically indicated at 500 and 600, respectively.

The control system 300 may be configured to control the first light generating devices 10 by pulse width modulation. The control system 300 may for example be configured to control a spectral power distribution of the light emitted by the light generating system 700 by controlling a duty cycle of the first device light 11.

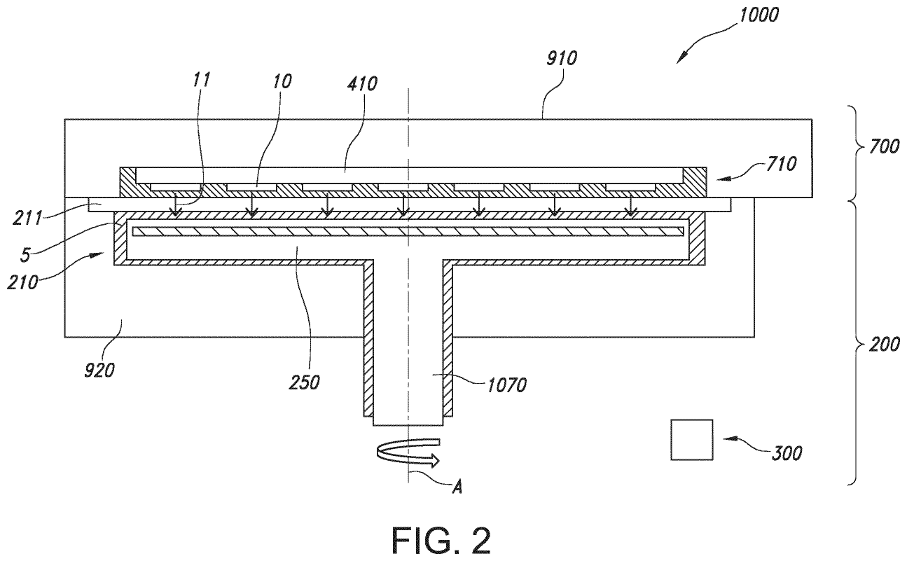

FIG. 2 is a schematic, in part sectional, side view of a photoreactor assembly 1000 according to another embodiment of the present invention. The same reference numerals in FIGS. 1 and 2 denote the same or similar elements, having the same or similar function. The photoreactor assembly 1000 illustrated in FIG. 2 may generally be configured in accordance with the photoreactor assembly 1000 illustrated in FIG. 1 and as described in the foregoing. However, according to the embodiment of the present invention illustrated in FIG. 2, the photoreactor 200 comprises a spinning disk reactor, wherein the spinning disk reactor comprises a disk 250 at least partly configured in the reaction chamber 210.

The photoreactor assembly 1000 illustrated in FIG. 2 comprises a rotor 1070 and a stator (not shown in FIG. 2), wherein the rotor 1070 is functionally coupled to the disk 250 or comprises the disk 250. The rotor 1070 is configured to rotate about an axis A of rotation, and by the functional coupling of the rotor 1070 with the disk 250 or by the disk 250 being comprised in the rotor 1070, the disk 250 is configured to be rotated about the axis A of rotation of the rotor 1070.

The photoreactor assembly 1000 illustrated in FIG. 2 may comprise an electrical power system (not shown in FIG. 2), which may be configured to provide power to the rotor 1070 via the stator for rotating the disk 250, and which may further be configured to provide power to the light generating system 700 and thereby to the first light generating devices 10. The electrical power system may for example comprise or be constituted by an electrical induction-based electrical power system. The control system 300 may be configured to control operation of the electrical power system. The control system 300 may be configured to control the power that is provided to the rotor 1070 by the electrical power system, and thereby to control a rotational speed of the disk 250, and the power that is provided to the light generating system 700 by the electrical power system.

It is to be understood that while the embodiment of the present invention illustrated in FIG. 2 relates to a spinning disk reactor, it is to be understood that this exemplifying and merely for illustrating principles of embodiments of the present invention. Embodiments of the present invention are not limited to photoreactor assemblies wherein the photoreactor is of a spinning disk reactor type. Rather, according to one or more other embodiments of the present invention, the photoreactor may be of, essentially, any other type of photoreactor than a spinning disk reactor type.

Although not shown in FIG. 2, the photoreactor assembly 1000 illustrated in FIG. 2 may possibly include a sensor, a user interface and/or a timer such as illustrated and described with reference to FIG. 1.

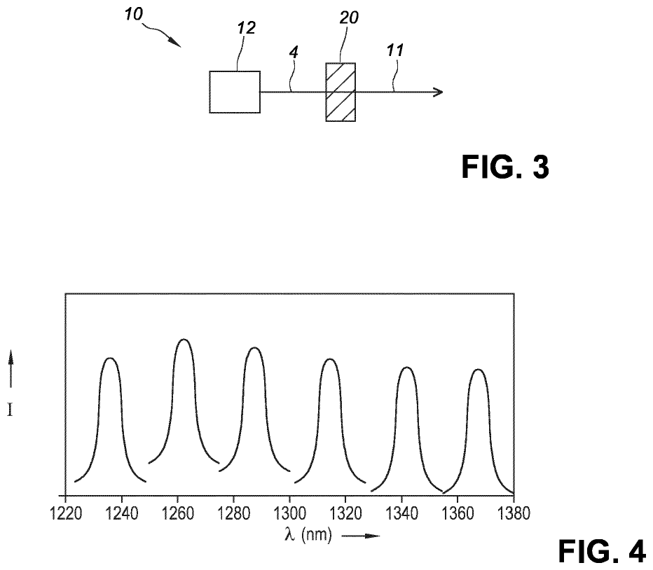

FIG. 3 is a schematic view of a first light generating device 10 of a photoreactor assembly in accordance with an embodiment of the present invention. The first light generating device 10 comprises a first light source 12 configured to generate first light source light 4. The photoreactor assembly comprises an upconverter material 20. The upconverter material 20 is arranged in relation to the first light source 12 so as to receive the first light source light 4. The upconverter material 20 is configured to convert at least part of the first light source light 4 changing between the at least two centroid wavelengths into the first device light 11 changing between the at least two centroid wavelengths. The upconverter material 20 may for example comprise one or more of an upconverter luminescent material and a frequency doubling material. The first light source 12 and the upconverter material 20 may for example be arranged such that the first light source light 4 comprises visible light or IR light, and such that the first device light 11 comprises or is constituted by UV light. Each or any of the first light generating devices 10 of the photoreactor assembly 1000 illustrated in FIG. 1 or 2 may be configured such as the first light generating device 10 illustrated in FIG. 3.

FIG. 4 schematically depicts intensity (in arbitrary unit) versus wavelength relating to light generated by a possible first light generating device comprising a wavelength tunable vertical cavity surface emitting laser (VCSEL). For example, the tunable visible laser light can be used to adjust the color point/color temperature. This can be achieved directly by the tunable visible laser light or indirectly by pumping a phosphor wherein the conversion rate depends on the pump wavelength. For the later configuration color separation elements (e.g., a dichroic for separating laser beams) may be used to enhance the effect. Several peaks are shown in FIG. 4. Intermediate peaks may be possible. For example, it is known that level of absorbance from a garnet phosphor at a given wavelength decreases with increasing temperature. As a result of this, the color point of the light source changes as a function of light intensity. A tunable blue laser can be used for compensating the temperature absorbance and hence keeping the color point of the phosphor with changing temperature. According to one or more embodiments of the present invention, after frequency doubling of a tunable IR laser emitting light in a wavelength range from 1240 nm to 1350 nm, a tunable red emitting laser emitting light in a wavelength range from 620 nm to 675 nm range can be obtained. Hence, with wavelength tunable light sources, which are tunable in the IR, also wavelength tunable light sources, which are tunable in the visible, may be obtained. In the same way, tunable IR emitting lasers emitting light in a wavelength range from 900 nm to 990 nm and 990 nm to 1140 nm can be used for producing tunable lasers emitting in blue wavelength range, 450 nm-495 nm and green wavelength range, 495 nm-570 nm, respectively.

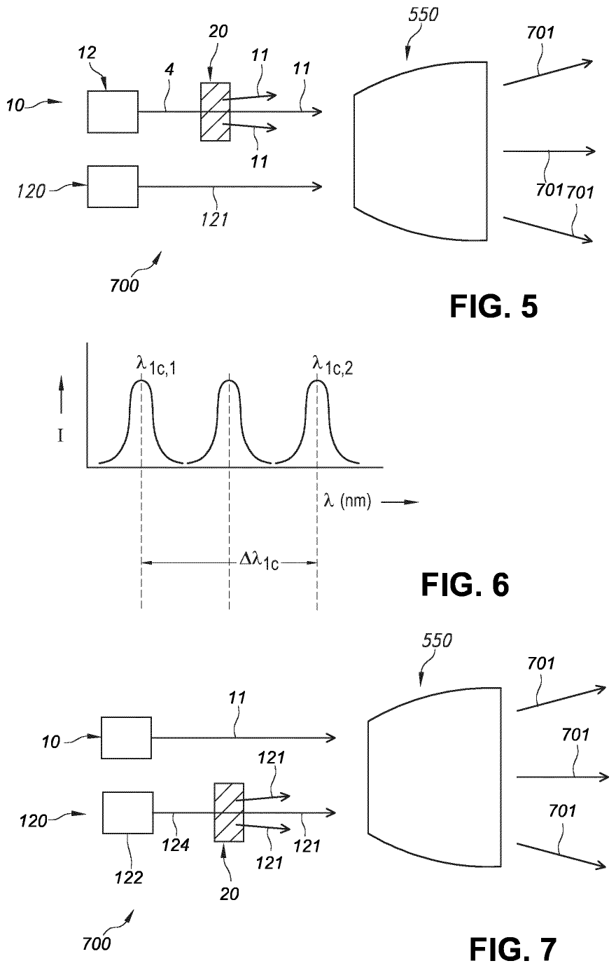

FIG. 5 is a schematic, in part sectional, view of a light generating system 700 of a photoreactor assembly in accordance with an embodiment of the present invention. The light generating system 700 comprises a first light generating device 10, a second light generating device 120, and an upconverter material 20, which for example may comprise a luminescent material. The first light generating device 10 may be configured to generate first device light 11. The second light generating device 120 may be configured to generate second device light 121. The first light generating device 10 comprises a first light source 12 configured to generate first light source light 4. The upconverter material 20 is arranged in relation to the first light source 12 so as to receive the first light source light 4. If the upconverter material 20 comprises a luminescent material, the upconverter material 20 may be configured to convert the first light source light 4 into the first device light 11 in the form of luminescent material light. The first device light 11 and the second device light 121 may have different spectral power distributions. The upconverter material 20 may comprise a luminescent material of the type A₃B₅O₁₂:Ce³⁺. A may comprise one or more of Y, La, Gd, Tb and Lu, and B may comprise one or more of Al, Ga, In and Sc. The light generating system 700 may comprise a ceramic body, and the ceramic body may comprise the upconverter material 20, e.g., a luminescent material. The element 550 represents optional optics, which may, e.g., comprise a beam shaping element like a collimator or lens. Other optics, not depicted, may also be possible. Optics 550 refer to optics arranged ‘downstream’ of the first light generating device 10, the second light generating device 120, and the upconverter material 20. The light generating system 700 is configured to generate system light 701 comprising the first device light 11 and the second device light 121.

FIG. 6 schematically depicts intensity (in arbitrary unit) versus wavelength relating to light generated by, e.g., the first light generating device 10 illustrated in FIG. 5. With reference to FIGS. 5 and 6, the first light generating device 10 (see FIG. 5) may be controllable at least with respect to the wavelength of the first device light 11, and may be configured to generate the first device light 11 such that it changes between at least two centroid wavelengths λ_{1c,1}, λ_{1c,2} having a wavelength difference (indicated in the drawing as Δλ_{1c}) of at least 10 nm, with a changing frequency of, e.g., at least 40 Hz. The first light generating device 10 may be described as a wavelength variable light generating device configured to generate, e.g., in an operational mode of the light generating system 700, the first device light 11 changing between the at least two centroid wavelengths λ_{1c,1}, λ_{1c,2}. The changing frequency may be smaller than 40 Hz, and may be at least 10 Hz, or it may be larger, such as at least 50 Hz or at least 60 Hz. The smallest wavelength band (on the left) may have centroid wavelengths λ_{1c,1}, and the largest wavelength band (on the right) may have centroid wavelengths λ_{1c,2}. Hence, these at least two centroid wavelengths λ_{1c,1}, λ_{1c,2} may be referred to as outer centroid wavelengths. The first light generating device 10 may comprise one or more of a vertical cavity surface emitting laser (VCSEL) and a superluminescent diode.

FIG. 7 is a schematic, in part sectional, view of a light generating system 700 of a photoreactor assembly in accordance with an embodiment of the present invention. The light generating system 700 comprises a first light generating device 10, a second light generating device 120, and an upconverter material 20, which for example may comprise a luminescent material. The first light generating device 10 may be configured to generate first device light 11. The second light generating device 120 may be configured to generate second device light 121. The second light generating device 120 comprises a second light source 122 configured to generate first light source light 124. The upconverter material 20 is arranged in relation to the second light source 122 so as to receive the first light source light 124. If the upconverter material 20 comprises a luminescent material, the upconverter material 20 may be configured to convert the second light source light 124 into the second device light 121 in the form of luminescent material light. The first device light 11 and the second device light 121 may have different spectral power distributions. The upconverter material 20 may comprise a luminescent material of the type A₃B₅O₁₂:Ce³⁺. A may comprise one or more of Y, La, Gd, Tb and Lu, and B may comprise one or more of Al, Ga, In and Sc. The light generating system 700 may comprise a ceramic body, and the ceramic body may comprise the upconverter material 20, e.g., a luminescent material. The element 550 represents optional optics, which may, e.g., comprise a beam shaping element like a collimator or lens. Other optics, not depicted, may also be possible. Optics 550 refer to optics arranged ‘downstream’ of the first light generating device 10, the second light generating device 120, and the upconverter material 20. The light generating system 700 is configured to generate system light 701 comprising the first device light 11 and the second device light 121.

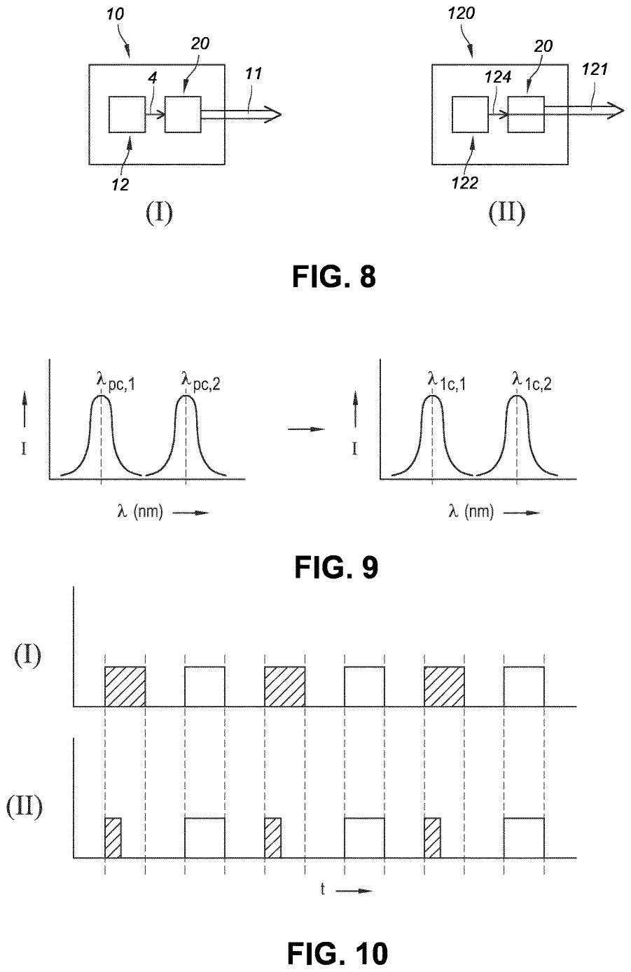

FIG. 8 is schematic views of a first light generating device 10 and a second light generating device 120 of a photoreactor assembly in accordance with embodiments of the present invention. The first light generating device 10 and the second light generating device 120 according to the illustrated embodiments are indicated as I and II in FIG. 8.

FIG. 9 schematically depicts intensity (in arbitrary unit) versus wavelength relating to light generated by, e.g., the first light generating device 10 and the second light generating device 120 illustrated in FIG. 8.

With reference to FIGS. 8 and 9, embodiment I, the first light generating device 10 may comprise a wavelength variable first light source 12 configured to generate, e.g., in an operational mode of the light generating system, first light source light 4 changing between the at least two centroid wavelengths λ_{pc,1}, λ_{pc,2}. having a wavelength difference of, e.g., at least 20 nm, with a changing frequency of, e.g., at least 50 Hz. Further, an upconverter material 20 arranged in relation to the first light source 12 so as to receive the first light source light 4 and configured to convert at least part of the first light source light 4 changing between the at least two centroid wavelengths λ_{pc,1}, λ_{pc,2} into the first device light 11 changing between the at least two centroid wavelengths λ_{1c,1}, λ_{1c,2}. The upconverter material 20 may for example comprise one or more of an upconverter luminescent material and a frequency doubling material. In embodiments, the first light source 12 may comprise an IR superluminescent diode or an IR vertical cavity surface emitting laser (VCSEL).

With reference to FIG. 8, embodiment II, the second light generating device 120 may comprise one or more of a diode laser and a superluminescent diode. In embodiments, the second light generating device 120 may comprise a VCSEL. The second light generating device 120 illustrated in FIG. 8 comprises a second light source 122 configured to generate, e.g., in an operational mode of the light generating system, second light source light 124 changing between the at least two centroid wavelengths having a wavelength difference of, e.g., at least 20 nm, with a changing frequency of, e.g., at least 50 Hz. Further, an (second) upconverter material 20 configured ‘downstream’ of the wavelength variable second light source 122 and configured to convert at least part of the second light source light 124 changing between the at least two centroid wavelengths into the second device light 121 changing between the at least two centroid wavelengths.

According to one or more embodiments of the present invention, the first light generating device 10 may be configured to generate first device light 11 having a centroid wavelength in a blue wavelength range and the second light generating device 120 may be configured to generate second device light 121 having a centroid wavelength in a red wavelength range. Alternatively, the first light generating device 10 may be configured to generate first device light 11 having a centroid wavelength in a (the) red wavelength range and the second light generating device 120 may be configured to generate second device light 121 having a centroid wavelength in a (the) blue wavelength range.

The control system (not shown in FIG. 8; cf., e.g., FIG. 1) may be configured to control the first light generating device 10 by pulse width modulation. For example, the control system may be configured to control a spectral power distribution of the light emitted by the light generating system by controlling a duty cycle of the first device light 11. The wavelength variable first light generating device 10 may be configured to generate first pulses of first device light 11 having the centroid wavelength λ_{1c,1} and second pulses of first device light 11 having the centroid wavelength λ_{1c,2}, each with a pulse frequency of, e.g., at least 40 Hz, wherein controlling the spectral power distribution of the light emitted by the light generating system may comprise individually controlling a duty cycle of first pules and a duty cycle of the second pulses. The control system may be configured to control the second light generating device 120 by pulse width modulation similarly or the same as the first light generating device 10 may be controlled by pulse width modulation.

FIG. 10 schematically illustrates examples of pulse width modulation, in accordance with two embodiments indicated by I and II in FIG. 10. The graphs indicate pulse intensity versus time t (in arbitrary units). Compared to embodiment I, in embodiment II, the pulse widths have been shortened. By shortening the pulse width in embodiment II, the contribution of the light provided in the first type of pulses to the light emitted by the light generating system may be reduced. In this way, the color may be tuned, e.g., along the black body locus. The two different pulses, indicated with non-hatched and hatched rectangles may refer to pulses of, e.g., first device light 11 having centroid wavelengths λ_{1c,1}, λ_{1c,2}, respectively. In this way, the light generating device (e.g., the first light generating device 10) may sweep between two (or more) different spectral power distributions, by which—particularly by means of pulse width modulation—the spectral power distribution of the light emitted by the light generating system may be controlled.

In conclusion, a photoreactor assembly is disclosed comprising a light generating system and a photoreactor. The light generating system comprises a first light generating device configured to generate first device light comprising one or more of ultraviolet light, visible light, and infrared light. The photoreactor comprises a reactor chamber configured to host a fluid to be treated with the first device light. The first light generating device is controllable at least with respect to the wavelength of the first device light, and is configured to generate the first device light such that it changes between at least two centroid wavelengths having a wavelength difference of at least 10 nm, e.g., with a selected changing frequency.

While the present invention has been illustrated in the appended drawings and the foregoing description, such illustration is to be considered illustrative or exemplifying and not restrictive; the present invention is not limited to the disclosed embodiments. Other variations to the disclosed embodiments can be understood and effected by those skilled in the art in practicing the claimed invention, from a study of the drawings, the disclosure, and the appended claims. In the appended claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A photoreactor assembly comprising a light generating system, a photoreactor, and a control system, wherein:
the light generating system comprises a first light generating device, wherein the first light generating device is configured to generate first device light comprising one or more of ultraviolet light, visible light, and infrared light, wherein the first light generating device comprises one or more of a laser and a superluminescent diode;
the photoreactor comprises a reactor chamber configured to host a fluid to be treated with the first device light, wherein the reactor chamber is configured in a light-receiving relationship with the first light generating device such that the first device light irradiates at least a part of the fluid;
the first light generating device comprises or is constituted by a wavelength variable light generating device that is controllable at least with respect to the wavelength of the first device light and configured to generate the first device light such that it changes between at least two centroid wavelengths (λ_{1c,1}, λ_{1c,2}) having a wavelength difference of at least 10 nm with a selected changing frequency; and
the control system is configured to obtain at least one of a signal generated by user input at a user interface, a signal generated by a sensor, or a signal generated by a timer, and control the first light generating device to generate the first device light responsive to the obtaining of the at least one of the signal generated by user input at the user interface, the signal generated by the sensor, or the signal generated by the timer.

2. The photoreactor assembly according to claim 1, wherein the laser comprises a vertical cavity surface emitting laser, VCSEL.

3. The photoreactor assembly according to claim 1, wherein the first light generating device is configured to generate the first device light such that it changes between the at least two centroid wavelengths with a changing frequency of at least 50 Hz.

4. The photoreactor assembly according to claim 1, wherein the at least two centroid wavelengths have a wavelength difference of at least 30 nm.

5. The photoreactor assembly according to claim 1, wherein the first light generating device comprises a first light source configured to generate first light source light, and wherein the photoreactor assembly further comprises an upconverter material arranged in relation to the first light source so as to receive the first light source light and configured to convert at least part of the first light source light changing between the at least two centroid wavelengths into the first device light changing between the at least two centroid wavelengths.

6. The photoreactor assembly according to claim 5, wherein the upconverter material comprises one or more of an upconverter luminescent material and a frequency doubling material.

7. The photoreactor assembly according to claim 5, wherein the first light source and the upconverter material are arranged such that the first light source light comprises visible light or infrared light, and the first device light comprises or is constituted by ultraviolet light.

8. The photoreactor assembly according to claim 1, further comprising a second light generating device configured to generate second device light, wherein the second light generating device comprises one or more of a laser and a superluminescent diode, wherein the first device light and the second device light have different spectral power distributions, and wherein the light generating system is configured to generate system light comprising the first device light and the second device light; wherein the reactor chamber is configured in a light-receiving relationship with the first light generating device and the second light generating device such that the system light irradiates at least a part of the fluid.

9. The photoreactor assembly according to claim 8, wherein the second light generating device comprises or is constituted by a wavelength variable light generating device and is controllable at least with respect to the wavelength of the second device light and is configured to generate the second device light such that it changes between at least two centroid wavelengths having a wavelength difference of at least 10 nm with a selected changing frequency.

10. The photoreactor assembly according to claim 9, wherein the first light generating device is configured to generate the first device light having a centroid wavelength in a first wavelength range and wherein the second light generating device is configured to generate the second device light having a centroid wavelength in a second wavelength range different from the first wavelength range.

11. The photoreactor assembly according to claim 1, wherein the control system is configured to control the first light generating device by pulse width modulation, wherein the control system is configured to control a spectral power distribution of the light emitted by the light generating system by controlling a duty cycle of the first device light.

12. The photoreactor assembly according to claim 1, the photoreactor comprises a spinning disk reactor, wherein the spinning disk reactor comprises a disk at least partly configured in the reaction chamber.

13. The photoreactor assembly according to claim 1, where the first light generating device comprises an array of at least ten lasers or an array of at least ten superluminescent diodes.

14. The photoreactor assembly according to claim 1, further comprising one or more of a sensor, a user interface or a timer.

15. The photoreactor assembly according to claim 14, comprising a sensor, wherein the sensor is configured to sense one or more of a flow rate of the fluid, a conversion level of a chemical compound in the fluid, or a conversion rate of a chemical compound in the fluid.
